(19) United States
(12) Patent Application Publication
(10) Pub. No.: US 2013/0228662 A1
(43) Pub. Date: Sep. 5, 2013

(54) DEVICE FOR USING A TABLET COMPUTING DEVICE AS A SECOND DISPLAY

(71) Applicant: Andrew Bradford Green, Mt. Pleasant, SC (US)

(72) Inventor: Andrew Bradford Green, Mt. Pleasant, SC (US)

(21) Appl. No.: 13/409,394

(22) Filed: Mar. 1, 2012

(51) Int. Cl. H05K 7/00

(52) U.S. Cl. 248/229.1

(57) ABSTRACT

A device for attaching and presenting a tablet computing device, such as an iPad or iPad2 tablet, in close proximity to a personal computer monitor or display. The device comprises a strong flexible support arm of sufficient strength to hold a tablet computing device in a specific position. The arm may be omnidirectional, i.e., it flexes in all directions. The arm should be of sufficient length to allow the tablet computing device to be moved to a variety of different positions adjacent to the computer monitor. Multiple tablet computing devices can be used with a single personal computer monitor.

### FIELD OF INVENTION

This invention relates generally to a device for using a touchscreen tablet computing device as a second display in conjunction with a primary computer display or monitor. More particularly, this invention relates to a device for using an iPad or iPad2 tablet computing device as a second display.

### BACKGROUND OF THE INVENTION

Many consumers are now used to interacting with their smart phones and tablet computing devices, such as the iPad or iPad2 tablet, through touchscreens. These devices also provide a host of user-friendly, content-specific applications (or “apps”). When consumers use their personal computing system at work or home for tasks appropriate to that system, use of their more portable devices becomes less convenient. Standard personal computing systems use a non-touchscreen display or monitor. The tablet computing device, in particular, often remains in its bag or case, and is not easily and efficiently viewed or used while the personal computer or workstation also is being used.

Accordingly, what is needed is a way for a user to integrate the tablet computing device with the personal computer or workstation environment.

### SUMMARY OF INVENTION

In various exemplary embodiments, the present invention comprises a device or apparatus for attaching and presenting a tablet computing device, such as an iPad or iPad2 tablet, in close proximity to a personal computer monitor or display. The device comprises a strong flexible support arm of sufficient strength to hold a tablet computing device in a specific position. The arm may be omnidirectional, i.e., it flexes in all directions. The arm should be of sufficient length to allow the tablet computing device to be moved to a variety of different positions adjacent to the computer monitor.

At one end of the arm is a clip or similar means for holding the tablet computing device. The clip may be of any configuration suitable for securely holding the tablet computing device. In one embodiment, the clip is triangular in shape with two corner holders and a top holder. The iPad2 or similar tablet computing device is inserted into the clip by placing two corners (e.g., the bottom corners) of the iPad2 into the two corner holders, and gently pressing or clipping the top of the iPad2 into the top holder. No screws, bolts, straps or similar fasteners are needed.

In one embodiment, the clip is rotatably connected to the end of the arm by a ball joint or tip, which allows the tablet computing device secured in the clip to swivel, tilt and be rotated in any direction, thereby giving the user a multitude of viewing and positioning angles.

In another embodiment, the clip is removably attached to the end of the arm or the ball joint or tip. Alternatively, the ball joint is part of the clip, and the ball joint may be removably attached to the arm. This permits different sizes and configurations of clips to be used, suitable for different sizes and shapes of tablet computing devices. In yet another embodiment, the clip is adjustable so as to be adapted for different tablets. For example, the two corner holders may be extended diagonally outward from the center of the clip while the top holder remains fixed. Alternatively, the top holder also may be extended outwardly.

A mounting clamp is fastened to the opposite end of the arm. The mounting clamp may be a two-way clamp. The mounting clamp may be removably fastened to the arm, so that clamps of different sizes and configurations may be used. In one embodiment, the mounting clamp may be covered or lined with a protective liner. The protective liner may be plastic, silicon, rubber, paper, cardboard, wood, or a similar material. The clamp may be spring-loaded, or may be tightened by means of an Allen wrench or similar means.

The clamp is used to securely fasten that end of the arm to a computer stand so the tablet computing device held in the clip may be positioned in a variety of different locations adjacent to the computer monitor or display. In one embodiment, the clamp is configured to clamp securely to the L-shaped monitor stand for an iMac or Apple computer monitor. In this position, the weight of the tablet is borne directly by the monitor stand, as opposed to being attached to an edge of the monitor itself (which can result in the monitor being off-balance and tipping). It also permits the iPad2 or other tablet to be positioned adjacent to the computer monitor in any desired position, including along either side or the top of the monitor, so that the tablet appears as a second or additional display that can be used simultaneously or in conjunction with the personal computer. Aesthetically, in several positions the tablet can be positioned so that it appears to “float” near the monitor, with no easily visible means of support or connection to the monitor. Further, due to the flexibility of the arm and the ball joint, the tablet can be easily moved and rotated to different positions around the monitor without moving the position of the clamp.

In yet a further embodiment, two or more tablets can be attached to the same monitor stand, allowing multiple tablets to be positioned adjacent to the monitor.

Accordingly, the tablet computing device or devices may be used in conjunction with a personal computer to become a multiple computing device workstation. The user can use applications on the tablet (or tablets) in conjunction with the personal computer. Thus, for example, the user can stream Pandora or similar application on an iPad2 while processing an iMovie project on their iMac personal computer. Or the tablet can display a chat, Twitter feed, favorite live weather application, or similar application. Alternatively, the tablet (or tablets) can be connected to the personal computer to be used as an additional monitor directly controlled by the personal computer, thereby providing a multiple-monitor workstation.

Additionally, the clamp also may be used to fasten the arm to an edge of a desk, countertop, piano, kitchen cabinets, or similar items. This enables the tablet to be used in the kitchen, for example, to display a recipe or cooking application, or stream a how-to video, while the tablet is held safely above the counter, away from possible spills or splatters. Or it may be used with a piano, or other musical instrument, while displaying a musical application. A mouse or keyboard, or both, also may be used with the tablet device in this configuration to effectively create a mini- or micro-workstation. When used with a power cord, or other peripheral with a cord, cable clips may be used to removably secure the cable to the arm.

Further, the clamp may be used to fasten to the arm itself, forming a circle or loop in the arm. This configuration may be used as an independent support for the tablet, for example, when the circle or loop is used as a based. Alternatively, the circle or loop can serve as a handle or gaming interface, such as a driver's wheel for a driving game or app being played on the tablet.

### BRIEF DESCRIPTION OF THE DRAWINGS

FIG. 1 shows a front view of an embodiment of the present invention being used to position a tablet computer device adjacent to a computer monitor.

FIG. 2 shows a back view of FIG. 1.

FIG. 3 shows a view of an embodiment of a tablet holding clip.

FIG. 4 shows a view of an embodiment of a mounting clamp.

FIG. 5 shows a view of two tablet computer devices being positioned adjacent to a computer monitor.

FIG. 6 shows a view of an embodiment of the present invention being used to position a tablet computing device in a kitchen.

FIG. 7 shows a view of an embodiment of the present invention being used to create a micro-workstation.

FIG. 8 shows a view of an embodiment of the present invention being used to position a tablet computer device on a desktop.

FIG. 9 shows a view of cable management clips being used in conjunction with the present invention.

### DETAILED DESCRIPTION OF EXEMPLARY EMBODIMENTS

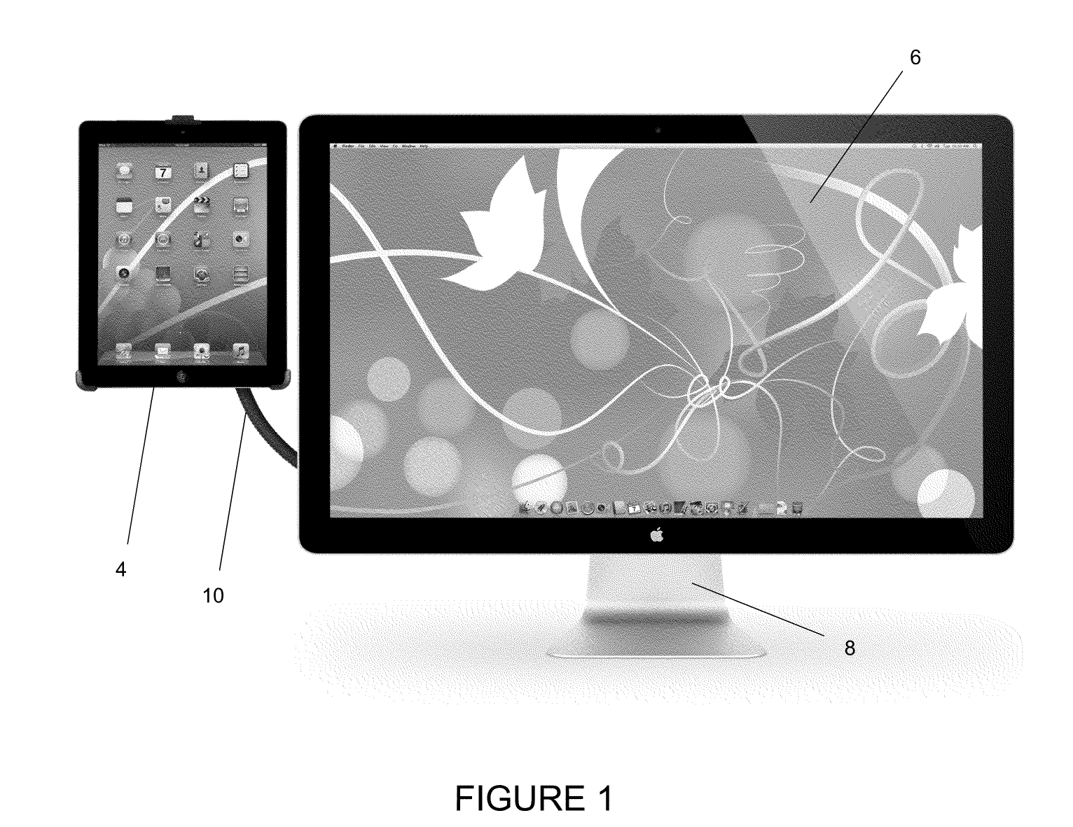

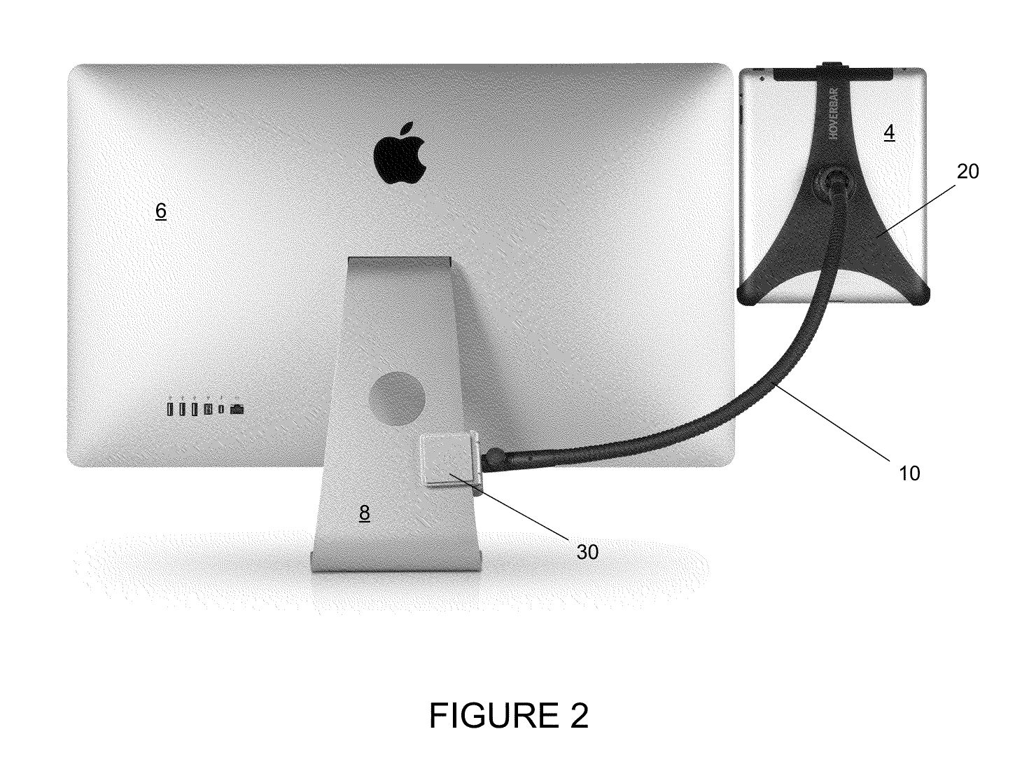

In various exemplary embodiments, as described herein, and as seen in FIGS. 1 and 2, the present invention comprises a device 2 for attaching and presenting a tablet computing device 4, such as an iPad or iPad2 tablet, in close proximity to a personal computer monitor or display 6. The device 2 comprises a strong flexible support arm 10 of sufficient strength to hold a tablet computing device in a specific position. The arm may be omnidirectional, i.e., it flexes in all directions. The arm should be of sufficient length to allow the tablet computing device 4 to be moved to a variety of different positions adjacent to the computer monitor 6.

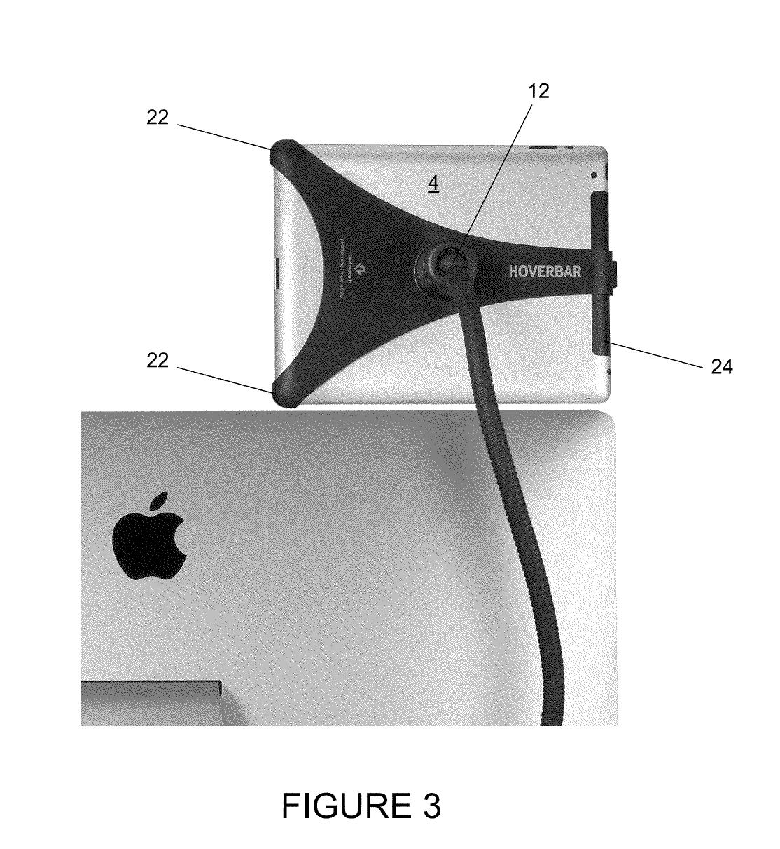

At one end of the arm is a clip 20 or similar means for holding the tablet computing device. The clip may be of any configuration suitable for securely holding the tablet computing device. In the embodiment shown in FIGS. 2 and 3, the clip is triangular in shape with two corner holders 22 and a top holder 24. The iPad2 or similar tablet computing device is inserted into the clip 20 by placing two corners (e.g., the bottom corners) of the iPad2 into the two corner holders 22, and gently pressing or clipping the top of the iPad2 into the top holder 24. No screws, bolts, straps or similar fasteners are needed.

In one embodiment, the clip 20 is rotatably connected to the end of the arm 10 by a ball joint or tip 12, which allows the tablet computing device secured in the clip 20 to swivel, tilt and be rotated in any direction, thereby giving the user a multitude of viewing and positioning angles.

In another embodiment, the clip 20 is removably attached to the end of the arm or the ball joint or tip. Alternatively, the ball joint is part of the clip, and the ball joint may be removably attached to the arm. This permits different sizes and configurations of clips to be used, suitable for different sizes and shapes of tablet computing devices. In yet another embodiment, the clip is adjustable so as to be adapted for different tablets. For example, the two corner holders 22 may be extended diagonally outward from the center of the clip while the top holder 24 remains fixed. Alternatively, the top holder 24 also may be extended outwardly.

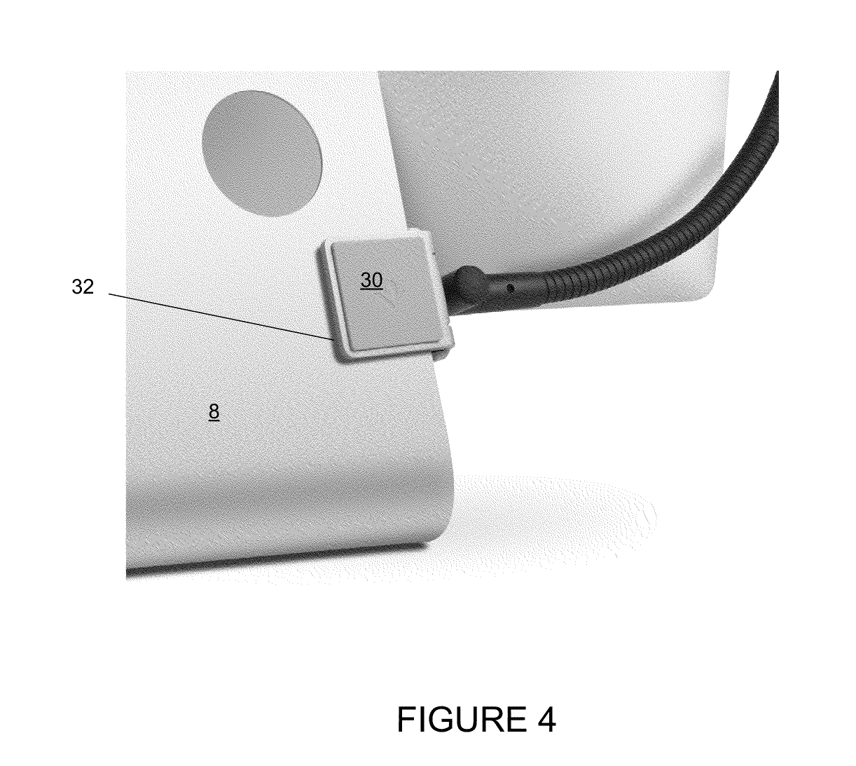

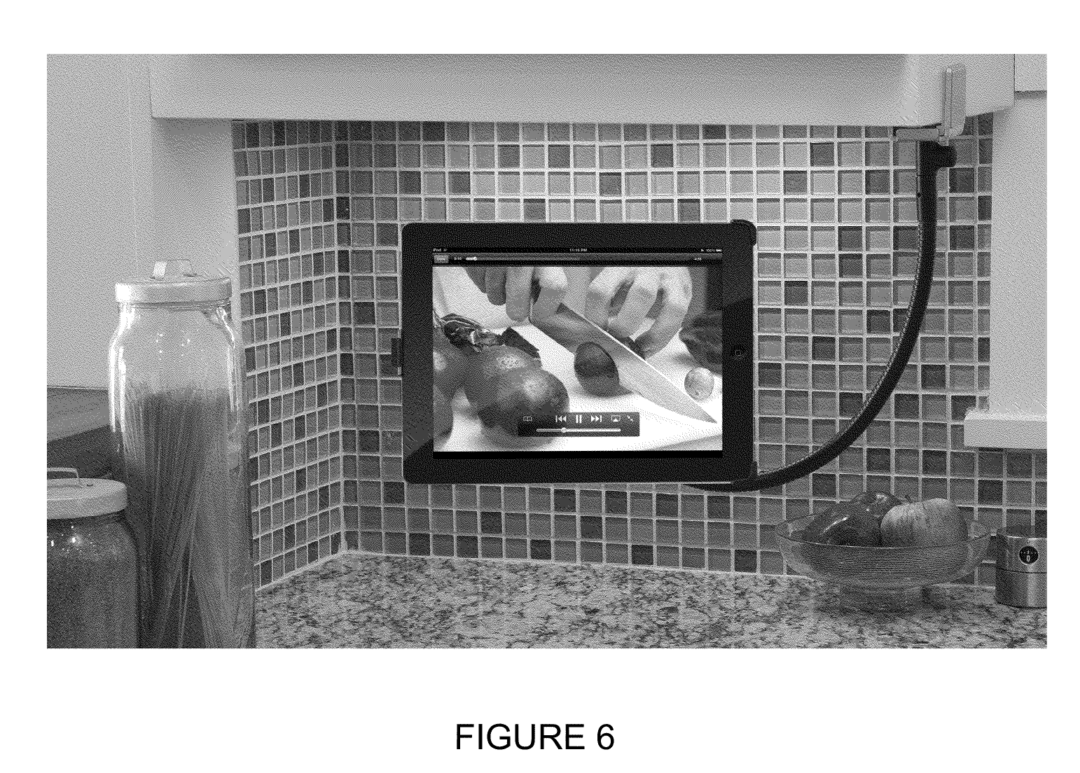

A mounting clamp 30 is fastened to the opposite end of the arm 10. The mounting clamp 30 may be a two-way clamp, as seen in FIGS. 4 and 6. The mounting clamp may be removably fastened to the arm, so that clamps of different sizes and configurations may be used. In one embodiment, the mounting clamp 30 may be covered or lined with a protective liner 32. The protective liner may be plastic, silicon, rubber, paper, cardboard, wood, or a similar material. The clamp may be spring-loaded, or may be tightened by means of a Allen wrench or similar means.

The clamp 30 is used to securely fasten that end of the arm to a computer stand so the tablet computing device held in the clip 20 may be positioned in a variety of different locations adjacent to the computer monitor or display. In one embodiment, the clamp 30 is configured to clamp securely to the L-shaped monitor stand 8 for an iMac or Apple computer monitor, as seen in FIG. 4. In this position, the weight of the tablet is borne directly by the monitor stand, as opposed to being attached to an edge of the monitor itself (which can result in the monitor being off-balance and tipping). It also permits the iPad2 or other tablet to be positioned adjacent to the computer monitor in any desired position, including along either side or the top of the monitor, so that the tablet appears as a second or additional display that can be used simultaneously or in conjunction with the personal computer. Aesthetically, in several positions the tablet can be positioned so that it appears to “float” near the monitor, with no easily visible means of support or connection to the monitor. Further, due to the flexibility of the arm and the ball joint, the tablet can be easily moved and rotated to different positions around the monitor without moving the position of the clamp.

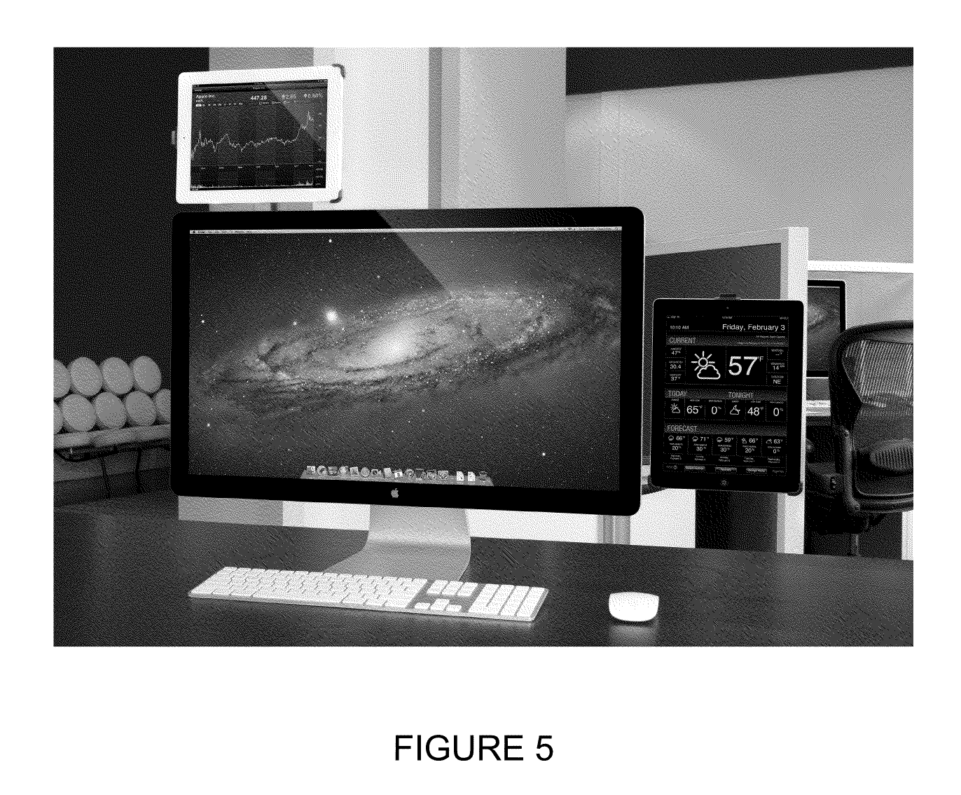

In yet a further embodiment, as seen in FIG. 5, two or more tablets can be attached to the same monitor stand, allowing multiple tablets to be positioned adjacent to the monitor. Accordingly, the tablet computing device or devices may be used in conjunction with a personal computer to become a multiple computing device workstation. The user can use applications on the tablet (or tablets) in conjunction with the personal computer. Thus, for example, the user can stream Pandora or similar application on an iPad2 while processing an iMovie project on their iMac personal computer. Or the tablet can display a chat, Twitter feed, favorite live weather application, or similar application. Alternatively, the tablet (or tablets) can be connected to the personal computer to be used as an additional monitor directly controlled by the personal computer, thereby providing a multiple-monitor workstation.

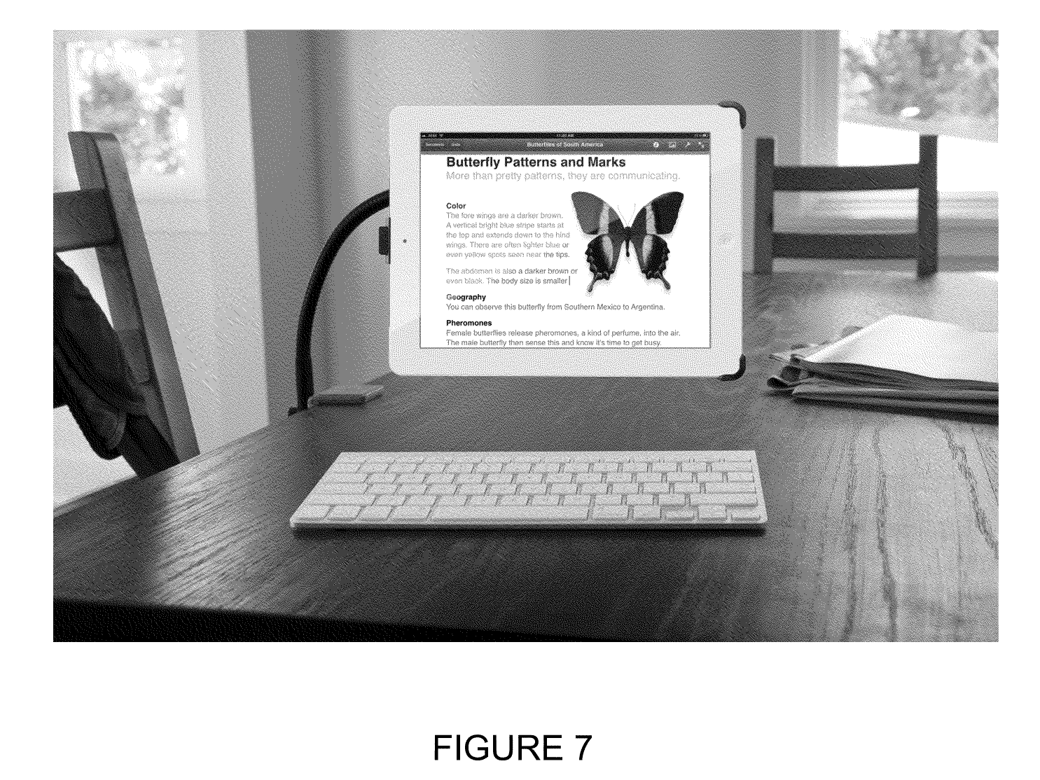

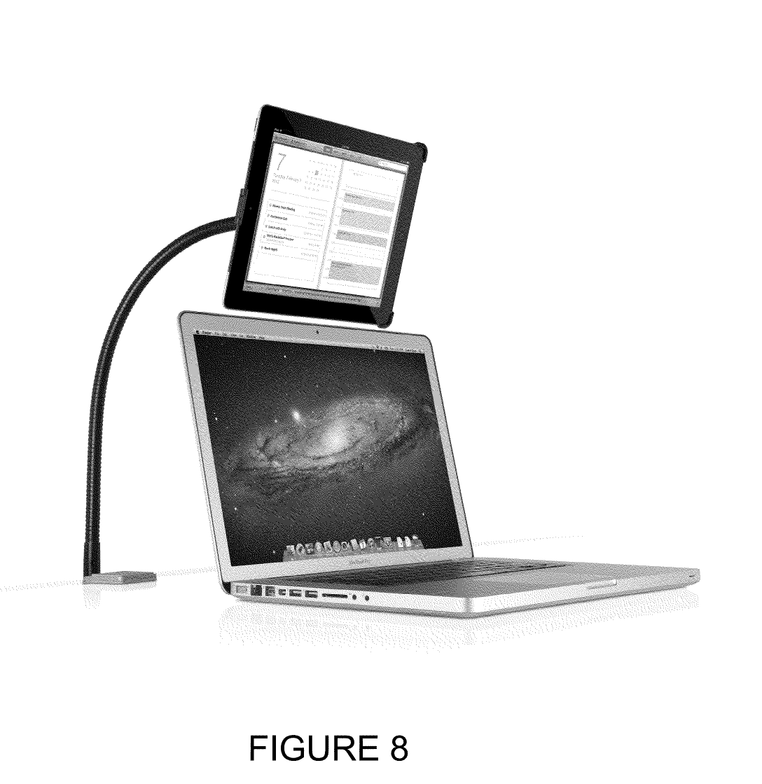

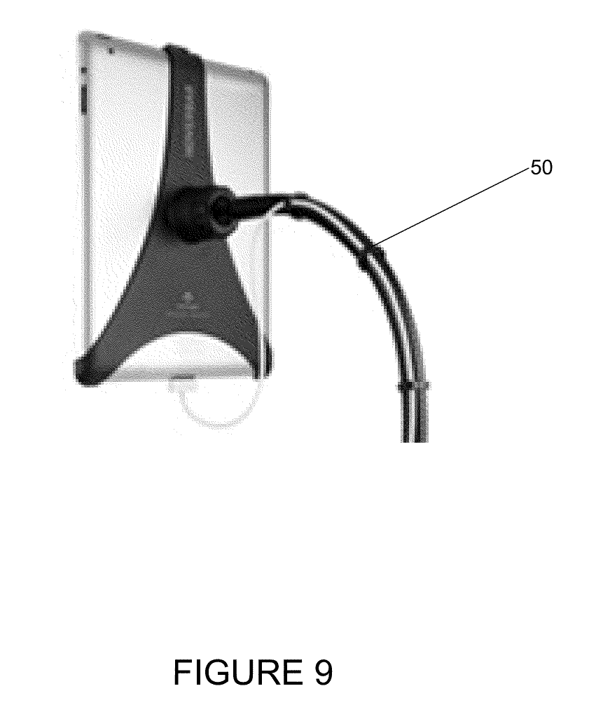

Additionally, the clamp also may be used to fasten the arm to an edge of a desk, countertop, piano, kitchen cabinets, or similar items, as seen in FIGS. 6-8. This enables the tablet to be used in the kitchen, for example, to display a recipe or cooking application, or stream a how-to video, while the tablet is held safely above the counter, away from possible spills or splatters. Or it may be used with a piano, or other musical instrument, while displaying a musical application. A mouse or keyboard, or both, also may be used with the tablet device in this configuration to effectively create a mini- or micro-workstation, as seen in FIG. 7. When used with a power cord, or other peripheral with a cord, cable clips 50 may be used to removably secure the cable to the arm, as seen in FIG. 9.

Further, the clamp may be used to fasten to the arm itself, forming a circle or loop in the arm. This configuration may be used as an independent support for the tablet, for example, when the circle or loop is used as a based. Alternatively, the circle or loop can serve as a handle or gaming interface, such as a driver's wheel for a driving game or app being played on the tablet.

In one exemplary embodiment, as seen in FIG. 2, the arm is 22 inches in length, although other suitable lengths may be used. The clamp may be used on items up to 1 inch thick, although different clamps may accommodate different thicknesses.

Thus, it should be understood that the embodiments and examples described herein have been chosen and described in order to best illustrate the principles of the invention and its practical applications to thereby enable one of ordinary skill in the art to best utilize the invention in various embodiments and with various modifications as are suited for particular uses contemplated. Even though specific embodiments of this invention have been described, they are not to be taken as exhaustive. There are several variations that will be apparent to those skilled in the art.

What is claimed is:

1. An apparatus for using a tablet computing device with a computer monitor, comprising:
a flexible arm with a first end and a second end;
a tablet holding clip rotatably fastened to the first end of the arm; and
a clamp fastened to the second end of the arm;
wherein the clamp is removably fastened to a computer monitor stand or edge of a desktop, countertop, or cabinet, and the tablet holding clip can be moved to a variety of positions around the computer monitor without moving the position of the clamp.

2. The apparatus of claim 1, wherein the tablet holding clip is adapted to securely hold the tablet computing device.

3. The apparatus of claim 1, wherein the tablet holding clip is rotatably fastened to the first end of the arm by a ball joint or tip.

4. The apparatus of claim 2, wherein the tablet computing device appears to float beside the computer monitor with no readily visible means of support.

5. The apparatus of claim 2, wherein the tablet computing device is used in conjunction with the personal computer to create a multiple computing device workstation.

6. The apparatus of claim 2, wherein the tablet computing device is used in conjunction with the personal computer to create a multiple-monitor workstation.

7. The apparatus of claim 1, further comprising a second apparatus of the same type so that two tablet computing devices are positioned adjacent to the computer monitor.

8. The apparatus of claim 2, wherein the tablet computing device is an iPad or iPad2.

9. The apparatus of claim 1, wherein the tablet holding clip is triangular in form, and comprises two corner holders and a single top holder.

10. The apparatus of claim 1, wherein the tablet holding clip is adjustable.

11. The apparatus of claim 1, wherein the clamp is lined.

12. The apparatus of claim 11, wherein the lining is silicon.

13. The apparatus of claim 1, wherein the arm is omnidirectionally flexible.
